(19) United States
(12) Patent Application Publication
(10) Pub. No.: US 2022/0176888 A1
(43) Pub. Date: Jun. 9, 2022

(54) VEHICLE MONITOR APPARATUS

(71) Applicant: Honda Access Corp., Saitama (JP)

(72) Inventors: Shingo Arao, Niiza-shi (JP); Hiroshi Hamada, Niiza-shi (JP); Masaru Kumaki, Niiza-shi (JP); Shunsuke Makino, Niiza-shi (JP); Shoji Murakami, Niiza-shi (JP); Hideki Hashimoto, Niiza-shi (JP)

(21) Appl. No.: 17/536,071

(22) Filed: Nov. 28, 2021

(30) Foreign Application Priority Data
Dec. 7, 2020 (JP) 2020-202358
Nov. 18, 2021 (JP) 2021-187839

(51) Int. Cl. B60R 11/02; B60Q 3/51; H05K 5/00; H05K 5/02

(52) U.S. Cl. CPC B60R 11/0229; B60Q 3/51; B60R 2011/0028; H05K 5/0204; H05K 5/0017

(57) ABSTRACT

A vehicle monitor apparatus including a mounting portion mounted on a ceiling surface in a vehicle cabin, a monitor portion including a base supported by the mounting portion, a light guide extending along a periphery of the base, and a spacer interposed between the base and the ceiling surface. The spacer is disposed inside a first area surrounded by the light guide and outside a second area in which the mounting portion is disposed, and composed of an elastic body elastically deformed by a compression force from the ceiling surface when the base is mounted on the ceiling surface through the mounting portion.

### CROSS-REFERENCE TO RELATED APPLICATION

This application is based upon and claims the benefit of priority from Japanese Patent Application No. 2020-202358 filed on Dec. 7, 2020 and Japanese Patent Application No. 2021-187839 filed on Nov. 18, 2021, the contents of which are incorporated herein by reference.

### BACKGROUND OF THE INVENTION

### Field of the Invention

This invention relates to a vehicle monitor apparatus mounted on a ceiling surface of a vehicle cabin.

### Description of the Related Art

As this type of apparatuses, there have been known monitor apparatuses that serve as a lighting fixture in the vehicle. Such an apparatus is described in, for example, Japanese Patent Publication No. 6058794 (JP6058794B). In the apparatus of JP6058794B, a light guide is disposed on the periphery of an approximately rectangular base member, and the base member is supported in a state in which the upper end of the wall of a holder supporting the light guide is in contact with the ceiling surface.

The ceiling surface may be formed into a gently curved surface, and the shape may vary among ceiling surfaces. For this reason, in the case of apparatuses configured such that the upper end of the wall of a holder contacts the ceiling surface, such as the apparatus of JP6058794B, some portions of the upper end may not sufficiently contact the ceiling surface, resulting in difficulty in illuminating the vehicle inside uniformly using the light guide.

### SUMMARY OF THE INVENTION

An aspect of the present invention is a vehicle monitor apparatus, including: a mounting portion mounted on a ceiling surface in a vehicle cabin; a monitor portion including a base supported by the mounting portion; a light guide extending along a periphery of the base; and a spacer interposed between the base and the ceiling surface. The spacer is disposed inside a first area surrounded by the light guide and outside a second area in which the mounting portion is disposed, and composed of an elastic body elastically deformed by a compression force from the ceiling surface when the base is mounted on the ceiling surface through the mounting portion.

### BRIEF DESCRIPTION OF THE DRAWINGS

The objects, features, and advantages of the present invention will become clearer from the following description of embodiments in relation to the attached drawings, in which:

FIG. 1 is an exploded perspective view of a vehicle monitor apparatus according to an embodiment of the present invention;

FIG. 2 is a perspective view showing a mounting state of the vehicle monitor apparatus according to the embodiment of the present invention;

FIG. 3 is a plan view of a monitor body included in the vehicle monitor apparatus according to the embodiment of the present invention;

FIG. 4 is a plan view of a spacer included in the vehicle monitor apparatus according to the embodiment of the present invention;

FIG. 5 is a perspective view showing a main configuration of the monitor body included in the vehicle monitor apparatus according to the embodiment of the present invention;

FIG. 6 is a plan view showing a further configuration of the monitor body included in the vehicle monitor apparatus according to the embodiment of the present invention;

FIG. 7 is a sectional view taken along line VII-VII of FIG. 5;

FIG. 8 is an enlarged view of main components of FIG. 7;

FIG. 9 is an enlarged perspective view of IX portion of FIG. 3;

FIG. 10 is an enlarged perspective view of X portion of FIG. 4;

FIG. 11 is a partial enlarged perspective view of a frame on which the vehicle monitor apparatus according to the embodiment of the present invention is mounted;

FIG. 12A is a perspective view showing an overall configuration of a sub-bracket;

FIG. 12B is a side view showing the overall configuration of the sub-bracket;

FIG. 13 is a perspective view showing a state in which the sub-bracket of FIG. 12A is mounted;

FIG. 14 is a side view showing the state in which the sub-bracket of FIG. 12A is mounted;

FIG. 15A is a drawing showing a first step for mounting the sub-bracket of FIG. 12A;

FIG. 15B is a drawing showing a second step following the first step of FIG. 15A;

FIG. 15C is a drawing showing a third step following the second step of FIG. 15B;

FIG. 15D is a drawing showing a fourth step following the third step of FIG. 15C;

FIG. 15E is a drawing showing a fifth step following the fourth step of FIG. 15D;

FIG. 15F is a drawing showing a sixth step following the fifth step of FIG. 15E;

FIG. 16 is a perspective view showing a state in which a stud bolt is inserted into the frame;

FIG. 17 is a perspective view of the stud bolt attached to the frame of FIG. 16;

FIG. 18 is a sectional view taken along line A-A of FIG. 16; and

FIG. 19 is a drawing showing a state in which the stud bolt attached to the frame is inclined.

### DETAILED DESCRIPTION OF THE INVENTION

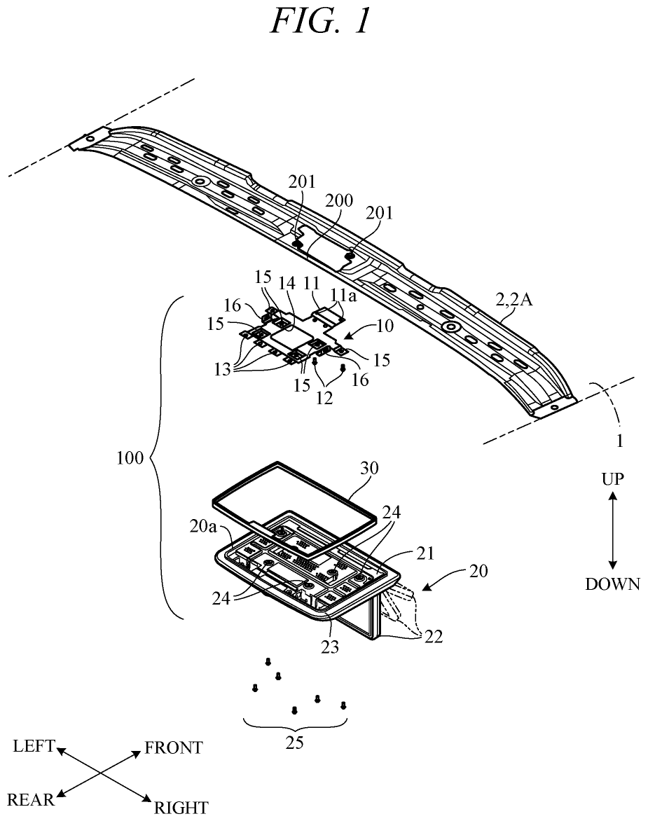

Hereinafter, an embodiment of the present invention will be described with reference to FIGS. 1 to 19. A vehicle monitor apparatus according to an embodiment of the present invention is installed at the central portion in the width direction on a ceiling surface in a cabin and is configured to show various images to the rear seat passengers.

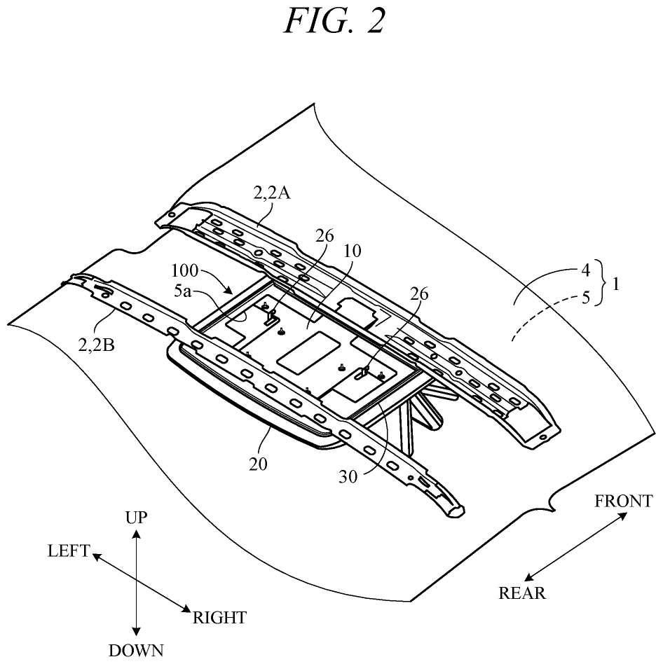

FIG. 1 is an exploded perspective view of a vehicle monitor apparatus 100 according to an embodiment of the present invention. FIG. 2 is a perspective view showing the mounting state of the vehicle monitor apparatus 100. For convenience, the front-rear direction (length direction), left-right direction (width direction), and up-down direction (height direction) of the mounted vehicle monitor apparatus 100 are defined as shown in the drawings. The configuration of the components will be described below in accordance with these definitions. FIGS. 1 and 2 are top, rear, and right perspective views of the vehicle monitor apparatus 100.

As shown in FIG. 2, the ceiling 1 of a vehicle includes a metallic, thin roof panel 4 that has an approximately rectangular shape in a plan view and extends so as to cover the outer surface of the vehicle and a roof lining 5 that is disposed opposite to the roof panel 4 and extends so as to face the inside of the vehicle cabin. The roof lining 5 is an interior material made of a resin or the like, and a hole having a predetermined shape can be easily bored in the roof lining 5 from the inside of the vehicle cabin using a tool such as a cutter. A pair of front and rear frames 2 are disposed between the roof panel 4 and roof lining 5 so as to be spaced from each other by a predetermined distance in the front-rear direction and to extend in the left-right direction. In the following description, the front frame 2 may be referred to as the front frame 2A, and the rear frame 2 as the rear frame 2B.

The frames 2 are arch-shaped strength members that extend between positions near the upper ends of center pillars (not shown) of the right and left ends of the ceiling 1. The frames 2 are disposed integrally with the roof panel 4. FIGS. 1 and 2 show components such as the frames 2 with the ceiling 1 being transparent for convenience.

As shown in FIGS. 1 and 2, the vehicle monitor apparatus 100 includes a bracket 10 mounted on the frames 2 of the ceiling 1 of the vehicle, a monitor body 20 mounted on the bracket 10, and a spacer 30 interposed between the ceiling 1 (roof lining 5) and monitor body 20. As shown in FIG. 2, an opening 5a having approximately the same shape as the external shape of the bracket 10 is formed in the roof lining 5. The bracket 10 is mounted on the frames 2 from the inside of the vehicle cabin through the opening 5a.

As shown in FIG. 1, an opening 200 for mounting the bracket 10 is formed in the central portion in the left-right direction of the front frame 2A. The opening 200 may be used to guide a cable, a harness, or the like connected to the monitor body 20 to above the front frame 2A.

The bracket 10 consists of a metallic plate member that has an approximately tabular shape and extends approximately horizontally. The front end of the bracket 10 is provided with a stay 11. The stay 11 has a pair of left and right through holes 11a. By screwing screws 12 passing through the through holes 11a into screw holes 201 formed in the frame 2 (front frame 2A), the stay 11 is fixed to the frame 2. The rear end of the bracket 10 is provided with four stays 13 that are used to fix the bracket 10 to the rear frame 2B and disposed in the left-right direction. The bracket 10 has an opening 14 having an approximately rectangular shape in a plan view in the central portion thereof. Three screw holes 15 are formed on each of the left and right sides of the opening 14. The left and right ends of the bracket 10 are provided with bent portions 16 that are bent upward.

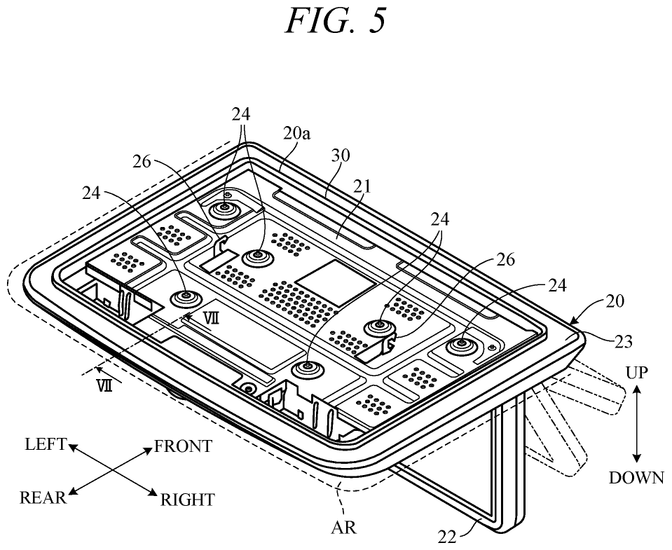

The monitor body 20 includes a base 21 having an approximately rectangular shape in a plan view and a monitor 22 supported by the front end of the base 21 so as to be rotatable in the front-rear direction using a hinge (see FIG. 5) extending in the left-right direction as a pivot. The base 21 includes a housing formed of a resin material or the like, and the housing houses electrical components. The base 21 is formed so as to be wider in the left-right direction than the bracket 10.

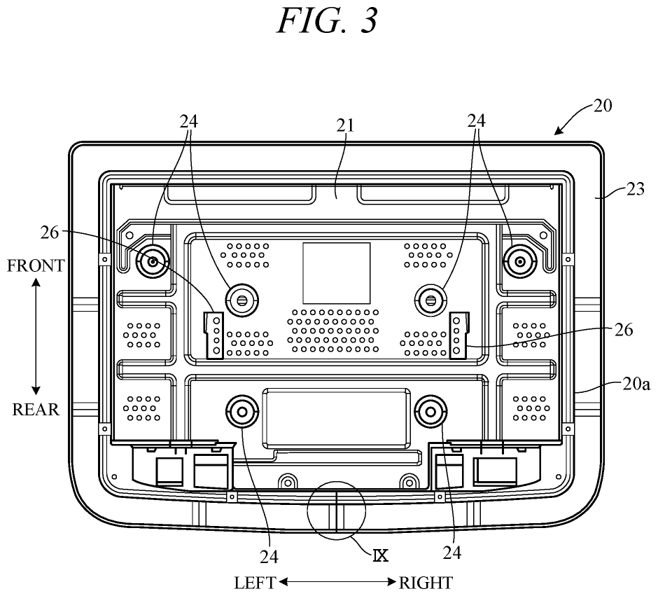

FIG. 3 is a plan view (top view) showing the external shape of the monitor body 20, in particular, the configuration of the upper surface of the base 21. As shown in FIGS. 1 and 3, a light guide panel 23 that is a part of the base 21 and has a rectangular frame shape is mounted on the periphery of the base 21. A mounting portion 20a of the spacer 30 is disposed along the inner circumferential edge of the light guide panel 23. The base 21 has through holes 24 corresponding to the screw holes 15 of the bracket 10 and passing through the base 21 in the up-down direction. By screwing screws 25 passing through the through holes 24 into the screw holes 15, the monitor body 20 is fixed to the bracket 10.

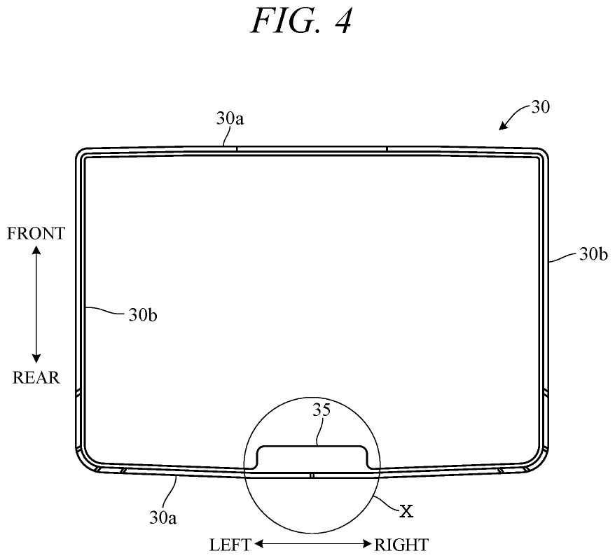

FIG. 4 is a plan view (top view) of the spacer 30. The spacer 30 is formed of an elastic rubber material or the like. As shown in FIGS. 1 and 4, the spacer 30 includes a pair of front and rear landscape portions 30a that extend in the left-right direction and a pair of left and right portrait portions 30b that extend in the front-rear direction. The spacer 30 is formed in a rectangular frame shape as a whole. A flat plate 35 protruding forward is disposed in the central portion in the left-right direction of the rear landscape portion 30a so as to be integral with the rear landscape portion 30a. A serial number or the like may be inscribed on the flat plate 35. Since the spacer 30 has shorter lengths (overall lengths) in the front-rear and left-right directions than the monitor body 20, it is mounted on the mounting portion 20a disposed on the upper surface of the monitor body 20 without protruding outward from the monitor body 20 in a plan view.

FIG. 5 is a perspective view showing the configuration of major components of the monitor body 20 having the spacer 30 mounted thereon. As shown in FIG. 5, a pair of left and right hooks 26 protruding in a forward-upward direction are fixed to the upper surface of the base 21. The hooks 26 are disposed in positions corresponding to the bent portions 16 (FIG. 1) of the bracket 10. Thus, after fixing the bracket 10 to the frames 2 and before fixing the monitor body 20 to the bracket 10, the hooks 26 are engaged with the bent portions 16 so that the monitor body 20 is hung from the ceiling 1. That is, the monitor body 20 is temporarily held. This facilitates the work of mounting the monitor body 20. The through holes 24 and hooks 26 are disposed inside the spacer 30.

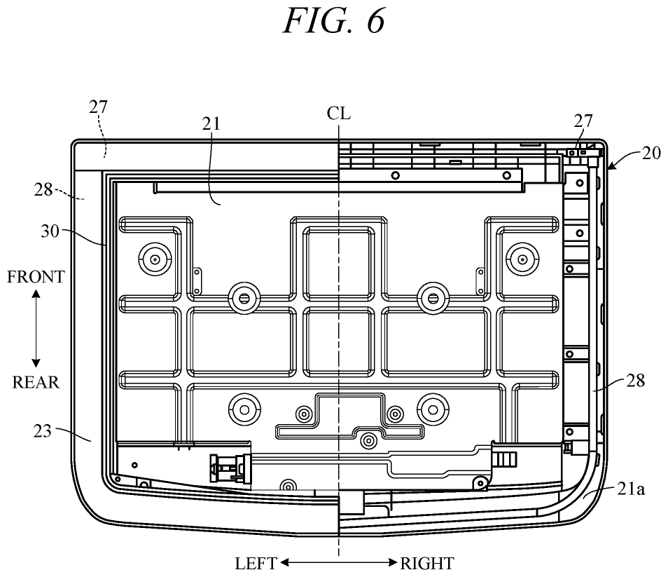

FIG. 6 is a plan view showing the configuration of the monitor body 20 (base 21) having the spacer 30 mounted thereon. While the upper surface of the base 21 is formed so as to be bilaterally symmetrical, FIG. 6 shows a state in which the light guide panel 23 is removed from the right side of a center line CL in the left-right direction of the base 21.

As shown in FIG. 6, a concave portion 21a is disposed along the periphery of the upper surface of the base 21, light sources 27 are disposed in the concave portion 21a on the front-right end and front-left end of the upper surface. The light sources 27 consist of, for example, LEDs capable of emitting RGB colors. Both ends of a light guide tube 28 having an approximately U-shape in a plan view disposed along the left, right, and rear edges of the base 21 are connected to the left and right light sources 27. The entire upper portion of the light guide tube 28 is covered by the light guide panel 23. When the light sources 27 are lighted with the monitor body 20 mounted on the ceiling 1, an area AR consisting of peripheral three edges of the monitor body 20 (an area inside a dotted line) is illuminated, as shown in FIG. 5. Thus, the vehicle monitor apparatus 100 is used as an indirect lighting fixture in the vehicle cabin.

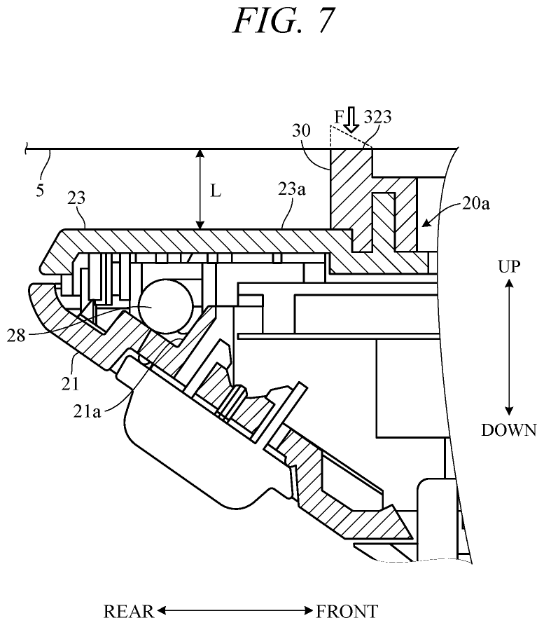

FIG. 7 is a sectional view showing the configuration of the periphery of the base 21 (a sectional view taken along line VII-VII of FIG. 5). FIG. 7 shows the surface of the ceiling 1 facing the inside of the vehicle cabin, that is, the lower end surface of the roof lining 5. As shown in FIG. 7, the light guide panel 23 is mounted on the periphery of the base 21, and the light guide tube 28 is disposed in the concave portion 21a of the base 21 so as to face the light guide panel 23. The inner circumferential edge (the front end in FIG. 7) of the light guide panel 23 extends inside the light guide tube 28, and the spacer 30 is mounted on the mounting portion 20a of the upper surface 23a of the inner circumferential edge.

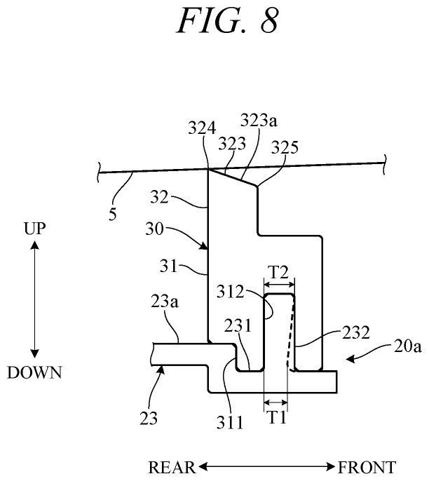

FIG. 8 is an enlarged view of main components of FIG. 7 showing the configuration of the mounting portion 20a of the spacer 30. As shown in FIG. 8, a concave portion 231 is disposed over the entire upper surface 23a of the inner circumferential edge of the light guide panel 23, and a protrusion 232 protruding to a position higher than the upper surface 23a is disposed along the inner circumferential edge inside the concave portion (the front side in FIG. 8). That is, the mounting portion 20a (FIG. 3) includes the concave portion 231 and protrusion 232. The protrusion 232 has an approximately rectangular section and is constant in the thickness in the up-down direction (the length in the front-rear direction in FIG. 8).

The spacer 30 includes a base 31 and a protrusion 32 that protrudes upward from the base 31. The thickness of the base 31 (the length in the front-rear direction in FIG. 8) is greater than that of the protrusion 32. More specifically, while the outer circumferential surface of the base 31 (the rear end surface in FIG. 8) is approximately flush with the outer circumferential surface of the protrusion 32, the inner circumferential surface of the base 31 is located inside (the front side in FIG. 8) the inner circumferential surface of the protrusion 32. The lower end surface of the base 31 has a concave and convex shape corresponding to the concave and convex shape of the upper surface 23a of the light guide panel 23. That is, a convex portion 311 and a concave portion 312 are formed over the entire lower end surface of the base 31 so as to be fitted to the concave portion 231 and the protrusion 232, respectively, of the light guide panel 23.

As with the concave portion 231, the convex portion 311 has an approximately rectangular section. On the other hand, as shown by a dotted line in FIG. 8, the width T1 on the entrance side (lower end side) of the concave portion 312 with a concave space, i.e., of the concave space is shorter than the width T2 on the back side (upper end side) thereof. That is, while the width T2 on the back side is the same as the thickness of the protrusion 232 (e.g., 2 mm), the width T1 on the entrance side is shorter than the thickness of the protrusion 232 (e.g., 1.5 mm). Thus, the concave portion 312 is fitted to the protrusion 232 while widening the concave portion 312 outward.

In this fitting state, the spacer 30 exerts the maximum pinching force on the base end of the protrusion 232. By forming the spacer 30 such that it holds the protrusion 232 in the concave portion 312, as described above, the stiffness of the spacer 30 is increased. That is, while, due to its rectangular frame shape, the spacer 30 has a short length (thickness) from the outer circumferential surface to the inner circumferential surface and thus tends to decrease in stiffness, the spacer 30 exhibits sufficient stiffness since it is formed such that it holds the protrusion 232 in the concave portion 312, that is, it is formed into a “hold-in” shape.

The outer circumferential surface (the rear end surface in FIG. 8) of the concave portion 312 is located approximately on a downward extension of the inner circumferential surface (the front end surface in FIG. 8) of the protrusion 32. Thus, when fitting the concave portion 312 to the protrusion 232, the width (the length in the front-rear direction) of the concave portion 312 is easily widened and therefore fitting is easy.

The protrusion 32 is formed so as to have an approximately rectangular section and has a tapered upper end surface 323. More specifically, the upper end 324 on the outer circumferential surface side of the protrusion 32 is located in a position higher than the upper end 325 on the inner circumferential surface side thereof by a predetermined length (e.g., about 2 mm). Also, the upper end surface 323 is formed so as to be inclined downward from the outer circumferential surface to the inner circumferential surface. That is, the upper end surface 323 is tapered at a predetermined inclination angle, and a tapered portion 323a is disposed over the entire upper end surface 323. Thus, when mounting the monitor body 20 on the bracket 10, the upper end 324 of the outer circumferential surface of the spacer 30 first contacts the lower surface of the roof lining 5.

The shape of the lower surface of the roof lining 5 slightly varies among vehicle types or vehicles. Also, the lower surface of the roof lining 5 may be formed so as to be curved. In the present embodiment, the upper end surface 323 of the spacer 30 is formed so as to be inclined and therefore the upper end of the spacer 30 can be easily elastically deformed. Thus, when the upper end 324 of the spacer 30 contacts the roof lining 5 during mounting of the monitor body 20, the upper end of the spacer 30 is crushed by a pressing force F from above, for example, as shown in FIG. 7. Thus, the entire perimeter of the spacer 30 contacts the lower surface of the roof lining 5 without clearance. That is, variations in the length L from the upper surface 23a of the light guide panel 23 to the lower surface of the roof lining 5 shown in FIG. 7 are easily accommodated by elastic deformation of the spacer 30.

Since the clearance between the entire perimeter of the spacer 30 and roof lining 5 is closed by elastic deformation of the spacer 30, the length L from the upper surface 23a of the light guide panel 23 to the lower surface of the roof lining 5 is kept approximately constant. Thus, the entire upper portion of the perimeter of the light guide panel 23 is uniformly illuminated, resulting in good illumination effects in the vehicle cabin.

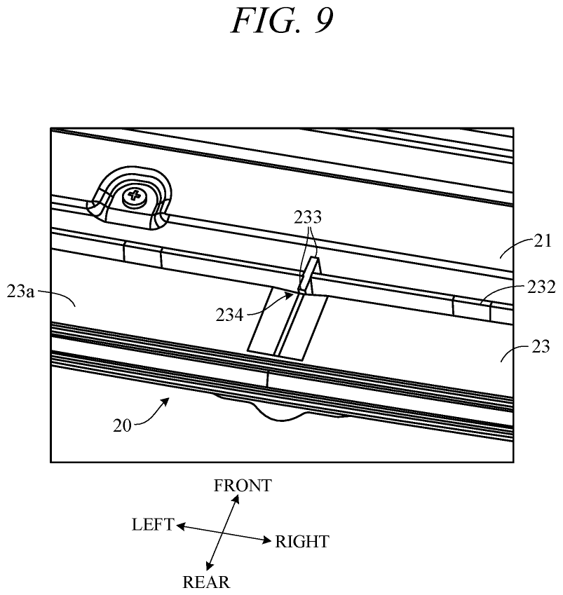

FIG. 9 is an enlarged perspective view showing the configuration of the mounting portion 20a of the spacer 30 on the central portion in the left-right direction of the rear end of the light guide panel 23 (an enlarged perspective view of IX portion of FIG. 3) and is a top perspective view of the mounting portion 20a. As shown in FIG. 9, ribs 233 having a predetermined length are disposed on front and rear portions of the upper surface 23a of the light guide panel 23 so as to cross the protrusion 232 extending in the left-right direction. That is, the protrusion 232 and ribs 233 form cross ribs 234 having an approximately cross shape in a plan view on the mounting portion 20a.

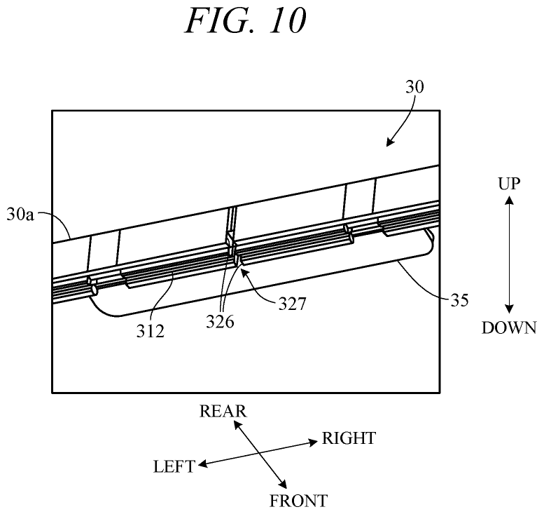

FIG. 10 is an enlarged perspective view showing the vicinity of the flat plate 35 disposed on the landscape portion 30a of the spacer 30 (an enlarged perspective view of X portion of FIG. 4) and is a bottom perspective view of the flat plate 35. As shown in FIG. 10, a concave portion 326 is disposed in the front-rear direction on the central portion in the left-right direction of the lower surface of the landscape portion 30a so as to cross the concave portion 312 extending in the left-right direction. That is, the concave portion 312 and concave portion 326 form a cross fitting portion 327 corresponding to the cross rib 234 on the landscape portion 30a.

When mounting the vehicle monitor apparatus 100 on the ceiling 1, the spacer 30 is previously mounted on the upper surface 23a of the light guide panel 23. Specifically, the concave portion 312 of the spacer 30 is pushed and fitted to the protrusion 232. Simultaneously, the cross rib 234 and cross fitting portion 327 are fitted to each other. Since the spacer 30 has a shape that is asymmetrical in the front-rear direction, it is prevented from being mounted reversely in the front-rear direction. Also, since the cross rib 234 is fitted to the cross fitting portion 327, positioning of the spacer 30 is facilitated, and further misregistration of the spacer 30 is prevented.

As shown in FIG. 1, the monitor body 20 having the spacer 30 mounted thereon is fixed to the bracket 10 through screws 25. For example, the bracket 10 is fixed to the frame 2 (front frame 2A) through the screws 12 and then the monitor body 20 is fixed to the bracket 10. In the present embodiment, the spacer 30 is in the shape of a rectangular frame and therefore is lightweight. Thus, the monitor body 20 having the spacer 30 mounted thereon is reduced in weight accordingly, making it easy to mount the monitor body 20. Also, the monitor body 20 is temporarily held on the bracket 10 using the hooks 26 (FIG. 3) on the upper surface of the monitor body 20. This makes it easier to mount the monitor body 20.

When mounting the vehicle monitor apparatus 100, the monitor body 20 may be fixed to the bracket 10 and then the bracket 10 integral with the monitor body 20 may be fixed to the frames 2 rather than first fixing the bracket 10 to the frame 2 (front frame 2A). That is, the stay 11 on the front end and the stays 13 on the rear end of the bracket 10 integral with the monitor body 20 may be fixed to the front frame 2A and rear frame 2B, respectively. In this case, the hooks 26 protruding from the upper surface of the monitor body 20 may be hung on the frame 2 in the middle of mounting of the bracket 10 so that the entire vehicle monitor apparatus 100 is temporarily held.

To improve the mountability of the vehicle monitor apparatus 100, the bracket 10 may be mounted on the frame 2 as follows. FIG. 11 is a partial enlarged perspective view of the rear frame 2B (a top perspective view). As shown in FIG. 11, the rear frame 2B has multiple slot holes 210 corresponding to the stays 13 on the rear end of the bracket 10. Sub-brackets having an anti-rotation function are inserted into the slot holes 210.

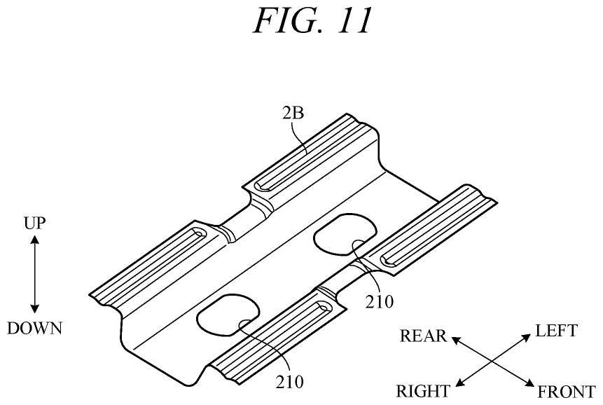

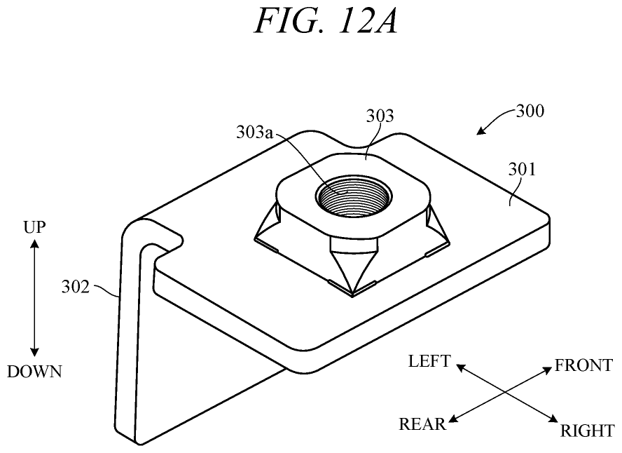

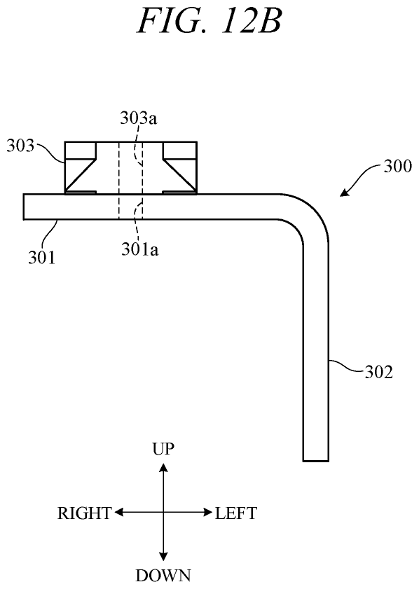

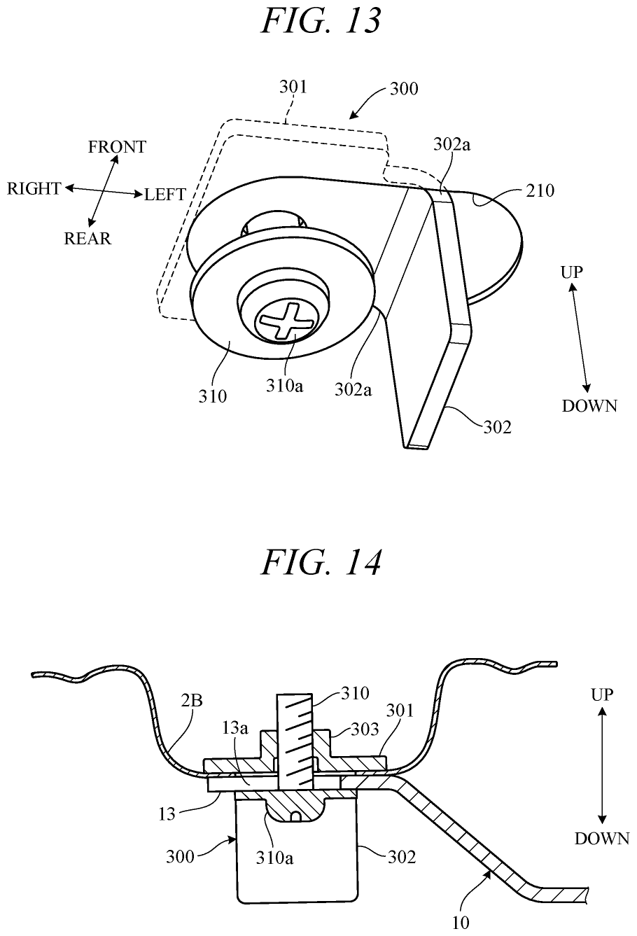

FIG. 12A is a perspective view showing the overall configuration of a sub-bracket 300, and FIG. 12B is a side view. FIG. 13 is a perspective view showing a state in which the sub-bracket 300 is mounted on the rear frame 2B (a bottom perspective view), and FIG. 14 is a sectional view. FIGS. 12A and 12B show the front-rear direction, left-right direction, and up-down direction of the sub-bracket 300 so as to correspond to direction shown in FIG. 13.

As shown in FIGS. 12A and 12B, the sub-bracket 300 is formed by bending a flat plate into an approximately L-shape and includes an approximately rectangular horizontal plate 301 that extends approximately horizontally and an approximately rectangular vertical plate 302 that extends downward from an end (the left end in the drawings) of the horizontal plate 301. A nut 303 is joined to the central portion of the upper surface of the horizontal plate 301. A through hole 301a is formed in the horizontal plate 301 along the screw hole 303a of the nut 303.

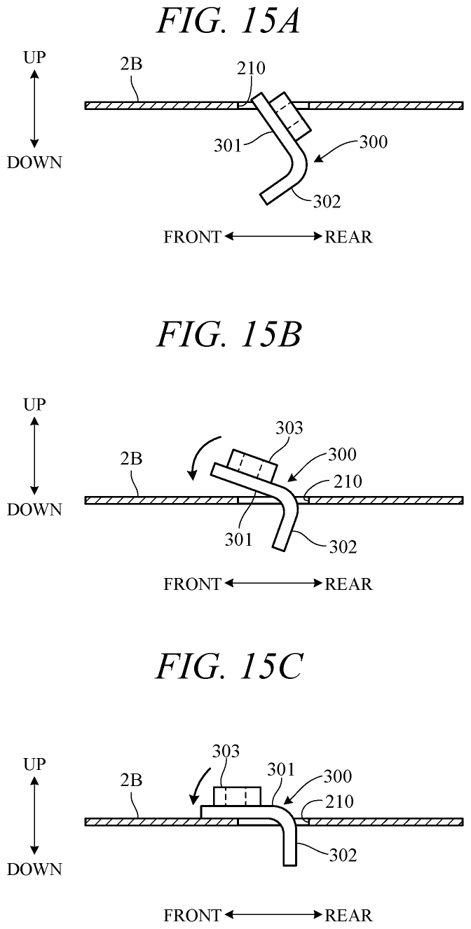

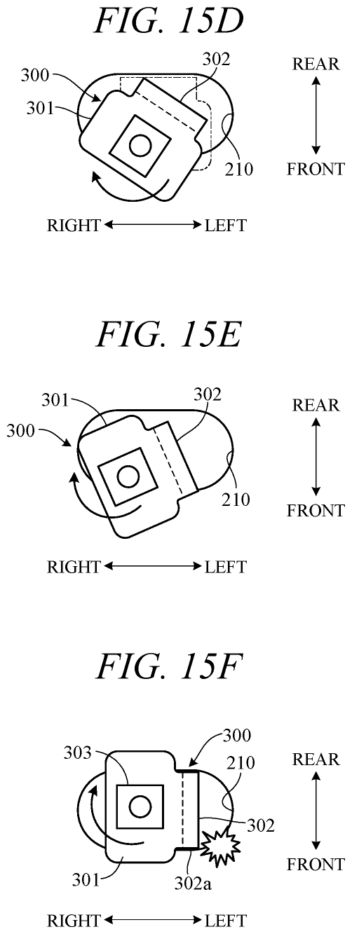

As shown in FIG. 13, the length in the front-rear direction of the horizontal plate 301 is longer the length in the front-rear direction of the slot hole 210, and the horizontal plate 301 is disposed over the slot hole 210 so as to cross the slot hole 210. The length in the front-rear direction of the vertical plate 302, in particular, the length in the front-rear direction of the upper end of the vertical plate 302 is equal to or slightly shorter than the length in the front-rear direction of the slot hole 210. Thus, when a bolt 310 is screwed to the screw hole 303a (FIG. 12B) of the nut 303 through the through hole 301a (FIG. 12B) from below the horizontal plate 301, a side surface 302a of the vertical plate 302 contacts the edge of the slot hole 210 and thus rotation in a predetermined direction (an arrow direction in FIG. 15F) of the sub-bracket 300 is blocked. The length in the front-rear direction of the horizontal plate 301 is shorter than the length in the left-right direction of the slot hole 210. Thus, the horizontal plate 301 is guided from below the rear frame 2B to above the rear frame 2B through the slot hole 210 with the horizontal plate 301 rotated from the state of FIG. 13 by 90°.

As shown in FIG. 14, the stay 13 (FIG. 1) of the rear end of the bracket 10 is sandwiched between the bottom of the rear frame 2B and the head 310a of the bolt 310 and thus fixed. More specifically, a notch 13a having a predetermined length is formed in the rear end of the stay 13 forward from the rear end surface of the stay 13. Thus, the rear end of the stay 13 is formed into an approximately U-shape. As shown in FIG. 13, when the stay 13 is inserted between the bottom of the rear frame 2B and the head 310a of the bolt 310 from the front with the bolt 310 loosened and locked to the nut 303, the bolt 310 is inserted into the notch 13a of the stay 13.

The width of the notch 13a is approximately equal to the diameter of the bolt 310. Thus, the edge of the notch 13a contacts the outer circumferential surface of the bolt 310 and thus the stay 13 are positioned. By rotating the head 310a of the bolt 310 through a tool in this state, the stay 13 is fixed, as shown in FIG. 14. At this time, as shown in FIG. 13, the side surface 302a of the vertical plate 302 contacts the edge of the slot hole 210 and thus rotation of the sub-bracket 300 is blocked. Thus, the bolt 310 is easily screwed into the nut 303 with the sub-bracket 300 kept at a predetermined position and a predetermined posture.

FIGS. 15A to 15F are drawings showing the steps (first to sixth steps) of mounting the sub-bracket 300. Specifically, the first-half mounting steps (first to third steps) are shown in FIGS. 15A to 15C, which are side views, and the second-half mounting steps (fourth to sixth steps) are shown in FIGS. 15D to 15F, which are plan views.

As shown in FIG. 15A, first, the tip of the horizontal plate 301 is inserted into the slot hole 210 by tilting the sub-bracket 300 with the longitudinal direction (the front-rear direction in FIG. 13) of the horizontal plate 301 aligned with the longitudinal direction of the slot hole 210 (the left-right direction in FIG. 13) (first step). Then, as shown in FIG. 15B, the nut 303 is passed through the slot hole 210 and then the horizontal plate 301 is rotated forward, as shown by an arrow (second step). Then, as shown in FIG. 15C, the horizontal plate 301 is placed on the upper surface of the rear frame 2B (third step). At this time, the angle of the sub-bracket 300 (vertical plate 302) with respect to the longitudinal direction of the slot hole 210 (the angle in a plan view is 0°. That is, the extending direction of the slot hole 210 and the extending direction of the vertical plate 302 are aligned with each other (a dot-dashed line in FIG. 15D), and this state is defined as 0°.

Then, as shown in FIGS. 15D and 15E, the sub-bracket 300 is rotated in an arrow direction (fourth step, fifth step). As shown in FIG. 15F, when the angle of the sub-bracket 300 with respect to the longitudinal direction of the slot hole 210 becomes 90°, that is, the sub-bracket 300 rotates by 90°, the side surface 302a of the vertical plate 302 contacts the edge of the slot hole 210 and thus rotation of the sub-bracket 300 is blocked (sixth step). Thus, the mounting of the sub-bracket 300 is complete.

The vehicle monitor apparatus 100 may be temporarily held in an inclined state considering the mountability and maintainability of the vehicle monitor apparatus 100. For example, the vehicle monitor apparatus 100 may be temporarily held through the stays 13 on the rear end of the bracket 10. An example of such a configuration will be described below. FIG. 16 is a partial enlarged perspective view of the rear frame 2B (a top perspective view).

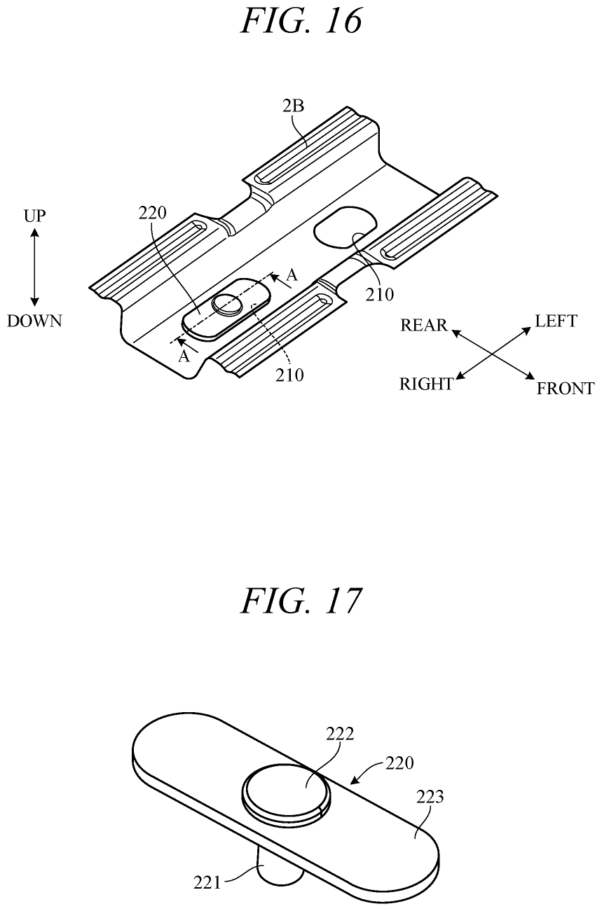

As shown in FIG. 16, a stud bolt 220 guided to above the rear frame 2B (between the rear frame 2B and roof panel 4) through a notch (not shown) disposed on the rear frame 2B is inserted into a slot hole 210 of the rear frame 2B. FIG. 17 is a perspective view of the stud bolt 220. The stud bolt 220 includes an approximately cylindrical screw 221 whose outer circumferential surface is threaded and a head 222 disposed on the upper end of the screw 221. An elongated plate 223 is integrally disposed on the head 222.

The diameter of the screw 221 is smaller than the width of the slot hole 210. On the other hand, the width of the plate 223 is smaller than the width (the length in the front-rear direction) of the slot hole 210, and the length of the plate 223 is longer than the length (the length in the left-right direction) of the slot hole 210. Thus, the stud bolt 220 is inserted into the slot hole 210 from below while tilting the plate 223. Once the stud bolt 220 is inserted into the slot hole 210, the stud bolt 220 can move along the slot hole 210 without passing through the slot hole 210 and falling.

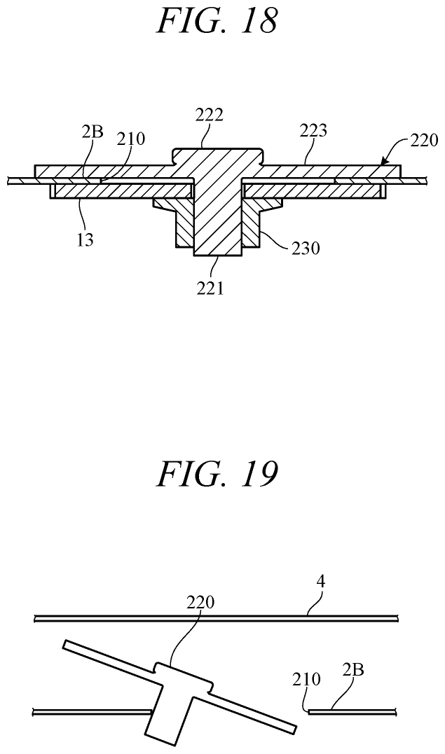

FIG. 18 is a sectional view taken along line A-A of FIG. 16 and shows a state in which the stay 13 of the rear end of the bracket 10 is fixed to the rear frame 2B. As shown in FIG. 18, a nut 230 is fastened to the screw 221 of the stud bolt 220 passing through the stay 13 (notch 13a or through hole), from below and thus the stay 13 is fixed to the rear frame 2B. When holding the vehicle monitor apparatus 100 in an inclined state, the screws 12 (FIG. 1) of the stay 11 of the front end of the bracket 10 are removed and the bracket 10 is supported on the frame 2 through the stay 13 in a cantilever state.

Further, the nut 230 is loosened so that the stud bolt 220 can move with respect to the rear frame 2B along with the stay 13. Thus, for example, as shown in FIG. 19, the stud bolt 220 is inclined along with the bracket 10 (not shown in FIG. 19) so that maintenance or the like can be performed on the vehicle monitor apparatus 100. In this case, maintenance is easily performed because the spacer 30 is only disposed on the periphery of the vehicle monitor apparatus 100 and the upper surface of the vehicle monitor apparatus 100 is mostly exposed.

The slot hole 210 may be formed so as to be a size larger than the plate 223 so that the plate 223 can be inserted into the slot hole 210 from below the frame 2 without having to incline the plate 223 of the stud bolt 220. In this case, the plate 223 is inserted into the slot hole 210 from below with the stud bolt 220 mounted on the stay 13 and with the nut 230 loosened. Then, the plate 223 is placed on the rear frame 2B by rotating the plate 223 by 90°. Thus, fall of the plate 223 is prevented, and the bracket 10 is temporarily held on the rear frame 2B through the stud bolt 220. Then, the front stay 11 is fixed to the front frame 2A through the screws 12 with the bracket 10 temporarily held. Also, the rear stays 13 are fixed to the rear frame 2B by fastening the nut 230 with the plate 223 rotated by 90°. Thus, the bracket 10 is easily mounted. This method allows the bracket 10 having the monitor body 20 previously mounted thereon to be mounted on the frames 2. Thus, the vehicle monitor apparatus 100 is easily mounted.

According to the present embodiment, following functions and effects can be exerted.

(1) The vehicle monitor apparatus 100 includes: the bracket 10 mounted on the ceiling 1 in the vehicle cabin; the monitor body 20 including the base 21 supported by the bracket 10; the light guide tube 28 extending along the periphery of the base 21; and the spacer 30 interposed between the base 21 and the ceiling 1 (roof lining 5) (FIGS. 1 and 6). The spacer 30 is disposed on the mounting portion 20a that is disposed inside the area surrounded by the light guide tube 28 and outside the area in which the bracket 10 is disposed (FIGS. 1, 5). The spacer 30 is composed of an elastic body that can be elastically deformed by a compression force from the ceiling 1 (roof lining 5) when mounting the base 21 on the ceiling 1 (FIG. 7).

This configuration allows the entire perimeter of the spacer 30 disposed in the area inside the light guide tube 28 to contact the ceiling 1 without clearance regardless of the shape of the ceiling surface, variations in the shape of the ceiling surface, or the like. Thus, the mounted vehicle monitor apparatus 100 shows a good appearance. Also, the distance L from the roof lining 5 to the light guide panel 23 (FIG. 7) is controlled using the spacer 30. Thus, when the light sources 27 are lighted, the periphery of the monitor body 20 is illuminated uniformly in the circumferential direction, that is, the vehicle monitor apparatus 100 favorably serves as a lighting fixture. Also, the spacer 30 is lightweight and therefore the monitor body 20 is easily mounted.

(2) The spacer 30 is formed along the light guide tube 28. The spacer 30 has the tapered portion 323a inclined downward toward the opposite side to the light guide tube 28 (the center side of the base 21), on the upper end surface 323 in contact with the ceiling 1 (FIG. 8). Thus, the upper end of the spacer 30 can be easily deformed. The tapered portion 323a is disposed on the inner circumferential surface side of the spacer 30 and therefore is not seen from the outside. That is, the spacer 30 has a good appearance.

(3) The base 21 (light guide panel 23) includes the protrusion 232 that protrudes upward (FIG. 8). The spacer 30 has the concave portion 312 with the concave space that is fitted to the protrusion 232. The concave portion 312 is formed such that the width T1 on the entrance side of the concave space is shorter than the width of the protrusion 232 and the width T2 on the back side is longer than the width T1 on the entrance side (FIG. 8). Thus, even if the spacer 30 is in the shape of a rectangular frame and is lightweight, the stiffness of the base 31 of the spacer 30 is sufficiently increased while the upper end (protrusion 32 side) is deformable. Therefore, the vehicle monitor apparatus 100 is stably supported through the spacer 30 in contact with the ceiling 1.

(4) The protrusion 232 includes the cross ribs 234 having an approximately cross shape in a plan view (FIG. 9). The concave portion 312 includes the cross fitting portion 327 formed into an approximately cross shape so as to be fitted to the cross rib 234 (FIG. 10). Thus, positioning of the spacer 30 with respect to the mounting portion 20a is facilitated, and the spacer 30 is prevented from being mounted reversely in the front-rear direction. Also, misregistration of the mounted spacer 30 is prevented.

(5) The vehicle monitor apparatus 100 includes the sub-brackets 300 inserted into the slot holes 210 of the rear frame 2B disposed on the ceiling surface (an attachment members) and attached thereto, and the bolts 310 that fix the bracket 10 to the sub-brackets 300 (a fixing member) (FIGS. 12A to 14). The sub-brackets 300 are disposed such that the angles with respect to the longitudinal direction of the slot holes 210 can be changed from a first angle (0°) at which the sub-brackets 300 are inserted into the slot holes 210 to a second angle (90°) at which rotation in a predetermined direction of the inserted sub-brackets 300 is blocked (FIGS. 15A to 15F).

Use of the sub-brackets 300 having such an anti-rotation function facilitates fixing of the stays 13, as well as facilitates mounting of the monitor body 20 on the ceiling surface of the vehicle through the bracket 10. Since the sub-brackets 300 contact the rear frame 2B in a small area during mounting of the sub-brackets 300, the sub-brackets 300 are accurately mounted in predetermined positions with respect to the slot holes 210 without interfering with a rib, wall, or the like disposed on the rear frame 2B. Thus, the bracket 10 is stably held on the ceiling surface with a predetermined fastening force through the bolts 310.

(6) The notches 13a (an engagement portion) are disposed on the rear ends of the stays 13 of the bracket 10. After the bolts 310 are inserted into the notches 13a, the bolts 310 are fastened to the nuts 303 (FIG. 14). Thus, the position of the bracket 10 is accurately defined. The configuration of the engagement portion that engages the bracket 10 serving as a mounting portion with the fixing member is not limited to the notches 13a.

(7) The vehicle monitor apparatus 100 is mounted on the frames 2 through the stud bolts 220. In this case, the base 21 is held through the bracket 10 so as to be inclined with respect to the ceiling 1 (FIGS. 18 and 19). The base 21 may be held in an inclined state through the hooks 26 disposed on the upper surface of the monitor body 20 (FIG. 5). Thus, maintenance or the like is easily performed on the vehicle monitor apparatus 100.

Various modifications of the above embodiment are possible. While, in the above embodiment, the stays 11 and 13 (a first mounting portion) of the bracket 10 are mounted on the pair of front and rear frames 2A and 2B on the ceiling surface in the vehicle cabin, the bracket as a mounting portion need not have the above configuration and may be mounted on a single frame. While, in the above embodiment, the base 21 of the monitor body 20 is supported on the screw holes 15 (a second mounting portion) of the bracket 10, a monitor portion including a base need not have the above configuration. While, in the above embodiment, the light guide tube 28 having an approximately U-shape in a plan view is disposed along the periphery of the base 21, a light guide may have any configuration as long as it is disposed along the periphery of the base.

While, in the above embodiment, the spacer 30 is formed into an approximately rectangular frame shape, a spacer interposed between the base and the ceiling surface need not have the above configuration. That is, the spacer may have any configuration as long as it is located inside the area (a first area) surrounded by the light guide and outside the area (a second area) in which the bracket (a mounting portion) is disposed and composed of an elastic body that can be elastically deformed by a compression force from the ceiling surface when mounting the base on the ceiling surface through the bracket. While, in the above embodiment, the tapered portion 323a is disposed on the entire upper end surface 323 of the spacer 30, an inclined portion need not have the above configuration and the tapered portion may be disposed on a part of the upper end surface.

In the above embodiment, the protrusion 232 (a rib) protruding upward is disposed on the light guide panel 23, which is a part of the base 21, the spacer 30 has the concave portion 312 engaged with the protrusion 232 (a fitting portion, in particular, a concave fitting portion), and the concave portion 312 is formed such that the width on the entrance side of the concave space is shorter than the width of the protrusion 232 and the width on the back side is longer than the width on the entrance side. However, a fitting portion need not have the above configuration. While, in above embodiment, the base 21 is temporarily held through the stud bolts 220 or hooks 26 so as to be inclined with respect to the ceiling surface, an inclination holding portion need not have the above configuration.

The above embodiment can be combined as desired with one or more of the above modifications. The modifications can also be combined with one another.

According to the present invention, a spacer can be made to contact a ceiling surface without gaps all around, and a light guide can illuminate the ceiling evenly.

Above, while the present invention has been described with reference to the preferred embodiments thereof, it will be understood, by those skilled in the art, that various changes and modifications may be made thereto without departing from the scope of the appended claims.

What is claimed is:

1. A vehicle monitor apparatus, comprising:
a mounting portion mounted on a ceiling surface in a vehicle cabin;
a monitor portion including a base supported by the mounting portion;
a light guide extending along a periphery of the base; and
a spacer interposed between the base and the ceiling surface, wherein
the spacer is disposed inside a first area surrounded by the light guide and outside a second area in which the mounting portion is disposed, and composed of an elastic body elastically deformed by a compression force from the ceiling surface when the base is mounted on the ceiling surface through the mounting portion.

2. The vehicle monitor apparatus according to claim 1, wherein
the spacer is formed along the light guide and includes a inclined surface inclined downward toward an opposite side of the light guide on an upper end surface in contact with the ceiling surface.

3. The vehicle monitor apparatus according to claim 1, wherein
the base includes a rib protruded upward,
the spacer includes a fitting portion fitted to the rib, and
the fitting portion is formed in a concave shape with a concave space so that a width on an entrance side of the concave space is shorter than a width of the rib and a width on a back side of the concave space is longer than the width on the entrance side.

4. The vehicle monitor apparatus according to claim 3, wherein
the rib includes a cross rib formed in a cross shape in a plane view, and
the fitting portion includes a cross fitting portion formed in a cross shape so as to be fitted to the cross rib.

5. The vehicle monitor apparatus according to claim 1, further comprising:
an attachment member inserted into a slot hole open in a frame provided at the ceiling surface to be attached to the frame; and
a fixing member fixing the mounting portion to the attachment member, wherein
the mounted member is installed in a rotatable manner so that an angle with respect to a longitudinal direction of the slot hole is changed from a first angle at which the attachment member is inserted into the slot hole to a second angle at which a rotation in a predetermined rotational direction of the attachment member inserted into the slot hole is blocked.

6. The vehicle monitor apparatus according to claim 5, wherein
the mounting portion includes a engagement portion engaging the fixing member.

7. The vehicle monitor apparatus according to claim 1, further comprising
an inclination holding portion configured to hold the base so as to be inclined with respect to the ceiling surface.

8. The vehicle monitor apparatus according to claim 1, wherein
the spacer is formed in a substantially rectangular frame shape, and
the base is supported by the mounting portion inside the spacer.

9. The vehicle monitor apparatus according to claim 1, wherein
the mounting portion is a bracket formed in a tabular shape, and
the bracket includes a first mounting portion mounted on the ceiling surface and a second mounting portion to which the monitor portion is attached.
